(19) United States
(12) Patent Application Publication
(10) Pub. No.: US 2025/0087980 A1
(43) Pub. Date: Mar. 13, 2025

(54) ELECTRICAL CONNECTION BOX

(71) Applicant: YAZAKI CORPORATION, Tokyo (JP)

(72) Inventors: Hirotaka Kiyota, Makinohara-shi (JP); Takeshi Onoda, Makinohara-shi (JP)

(21) Appl. No.: 18/961,360

(22) Filed: Nov. 26, 2024

Related U.S. Application Data
(63) Continuation of application No. PCT/JP2023/037612, filed on Oct. 18, 2023.

(30) Foreign Application Priority Data
Nov. 24, 2022 (JP) 2022-187137

(51) Int. Cl. H02G 3/16; B60R 16/033

(52) U.S. Cl. CPC H02G 3/16; B60R 16/033

(57) ABSTRACT

A tubular wall of a tubular portion of a frame includes a facing wall body, a cover member includes a cover main body, an outer peripheral wall body, a closing wall body and the outer peripheral wall body, an annular inner peripheral wall body, and a waterproof cover wall body, the inner peripheral wall body includes a waterproof wall portion that is fitted to a peripheral edge portion of the facing wall body that is on a side of the opening from the outside of the tubular portion and covers the peripheral edge portion of the facing wall body that is a part of the opening peripheral edge portion from the outside of the tubular portion, and the waterproof cover wall body protrudes from the outer peripheral wall body to a position where the circuit branching component is covered between the waterproof cover wall body and the facing wall body.

### CROSS-REFERENCE TO RELATED APPLICATION(S)

This application is a continuation application of International Application No. PCT/JP2023/037612 filed on Oct. 18, 2023 which claims the benefit of priority from Japanese Patent Application No. 2022-187137 filed on Nov. 24, 2022 and designating the U.S., the entire contents of which are incorporated herein by reference.

### BACKGROUND OF THE INVENTION

### 1. Field of the Invention

The present invention relates to an electrical connection box.

### 2. Description of the Related Art

In an electrical connection box, an electronic component such as a relay interposed between an external power supply and a load is housed in a housing. In the electrical connection box, an electric wire electrically connected to the electronic component is routed in the housing, and the electric wire is drawn out of the housing to be electrically connected to the power supply or the load. For example, the electrical connection box according to the related art is disclosed in Japanese Patent Application Laid-open No. 2014-93888.

Meanwhile, in recent vehicles, there is increasing adoption of electric wires that are difficult to bend, such as an electric wire that has a larger diameter to change a material of a core wire of the electric wire for weight reduction, or an electric wire that has a larger diameter for a large current. For this reason, in the electrical connection box, it is difficult to route the electric wire in a narrow space in the housing, and there is a possibility that an overload is applied to the periphery from the electric wire in the housing. In the electrical connection box, for example, it is possible to suppress an overload in the housing due to the electric wire by disposing such an electric wire and a component connected to the electric wire outside the housing. However, in this case, how to secure the waterproof property of the portion physically and electrically connected between the electric wire and the component connected to the electric wire becomes the next problem.

### SUMMARY OF THE INVENTION

Therefore, an object of the present invention is to provide an electrical connection box that can ensure waterproofness while suppressing an overload in a housing.

In order to achieve the above mentioned object, an electrical connection box according to one aspect of the present invention includes an electronic component; an internal conductive member that electrically connects the electronic component to an external power supply; a frame that includes a tubular portion that includes a tubular wall having an opening at least at one end and houses and holds the electronic component and the internal conductive member in the tubular portion; a cover member that is fitted to an opening peripheral edge portion of a peripheral edge of the opening of the tubular portion and closes the opening of the tubular portion; and a circuit branching component that is disposed outside the frame and outside the tubular portion and is interposed between the external power supply and an external load, wherein the frame is installed such that the opening of the tubular portion faces vertically upward, the internal conductive member includes a first electrical connection portion and a second electrical connection portion that are physically and electrically connected to the electronic component in the tubular portion, the circuit branching component includes a power supply connection portion that is electrically connected to a power-supply-side electric wire electrically connected to the external power supply and is physically and electrically connected to the second electrical connection portion of the internal conductive member, and a load connection portion that is electrically connected to a load-side electric wire electrically connected to the external load, the tubular wall of the tubular portion includes a facing wall body disposed to face the circuit branching component outside the tubular portion, the cover member includes a cover main body that is disposed to face the opening of the tubular portion, an annular outer peripheral wall body that covers the opening peripheral edge portion from an outside of the tubular portion, a closing wall body that closes a gap between the cover main body and the outer peripheral wall body, an annular inner peripheral wall body that is disposed at an interval from the outer peripheral wall body on an inner side of the outer peripheral wall body and is fitted to the opening peripheral edge portion, and a waterproof cover wall body that suppresses water splashing onto the circuit branching component, the inner peripheral wall body includes a waterproof wall portion that is fitted to a peripheral edge portion of the facing wall body that is on a side of the opening from the outside of the tubular portion and covers the peripheral edge portion of the facing wall body that is a part of the opening peripheral edge portion from the outside of the tubular portion, and the waterproof cover wall body protrudes from the outer peripheral wall body to a position where the circuit branching component is covered between the waterproof cover wall body and the facing wall body.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view illustrating an electrical connection box according to an embodiment;

FIG. 2 is a plan view of the electrical connection box according to the embodiment when viewed from a side of a frame;

FIG. 3 is a plan view of the electrical connection box (without a first cover member) according to the embodiment when viewed from one opening side of the frame;

FIG. 4 is a cross-sectional view taken along line X-x of FIG. 2;

FIG. 5 is an exploded perspective view illustrating the electrical connection box (without the first cover member and a second cover member) according to the embodiment;

FIG. 6 is an exploded perspective view of the frame and the first cover member in the electrical connection box according to the embodiment;

FIG. 7 is an exploded perspective view illustrating a block, and an internal conductive member and a male screw member housed in the block;

FIG. 8 is an exploded perspective view of the frame and the second cover member in the electrical connection box (without the first cover member) according to the embodiment;

FIG. 9 is a perspective view illustrating the first cover member;

FIG. 10 is an exploded perspective view for describing a load-side electrical connection structure;

FIG. 11 is a perspective view illustrating a circuit protection member;

FIG. 12 is an enlarged view for describing a power-supply-side electrical connection structure;

FIG. 13 is a perspective view illustrating the frame;

FIG. 14 is a partially enlarged view taken along line Y-Y of FIG. 2; and

FIG. 15 is a perspective view illustrating a first divided cover.

### DETAILED DESCRIPTION OF THE PREFERRED EMBODIMENTS

Hereinafter, an embodiment of an electrical connection box according to the present invention will be described in detail with reference to the drawings. Note that the present invention is not limited by the embodiment.

### EMBODIMENT

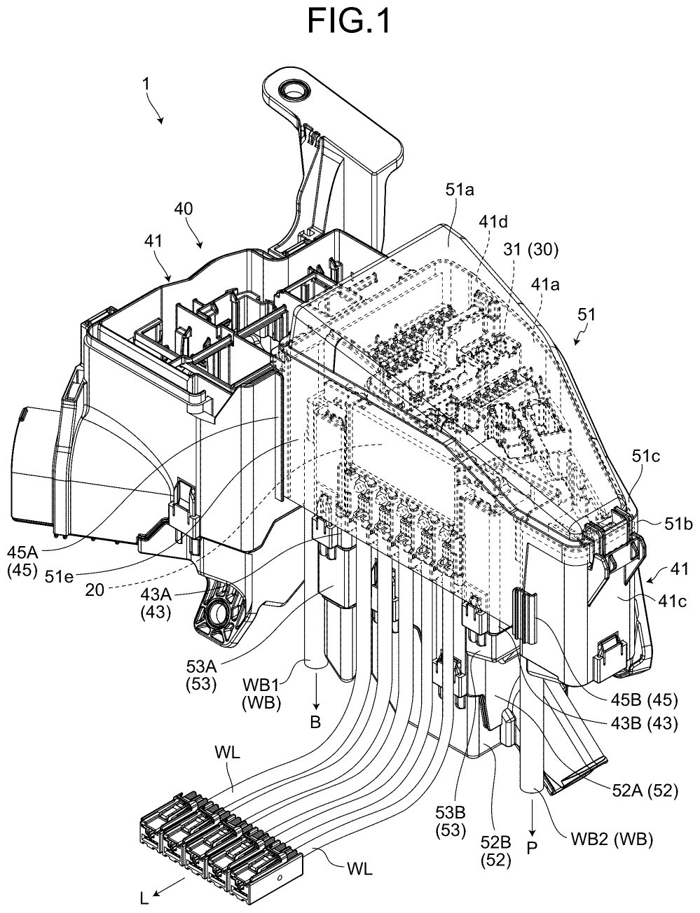

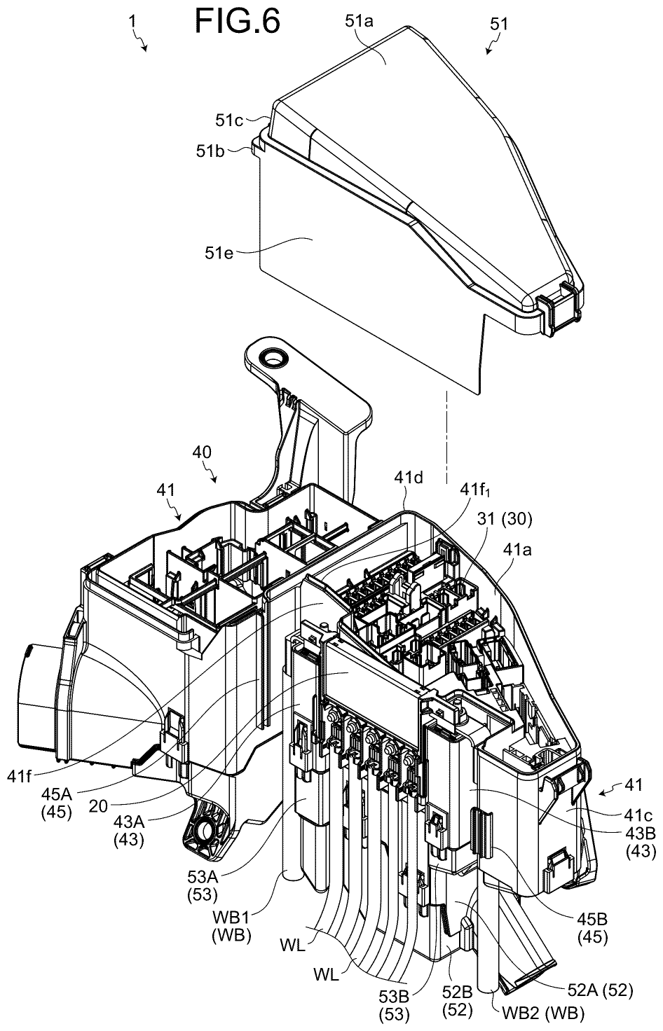

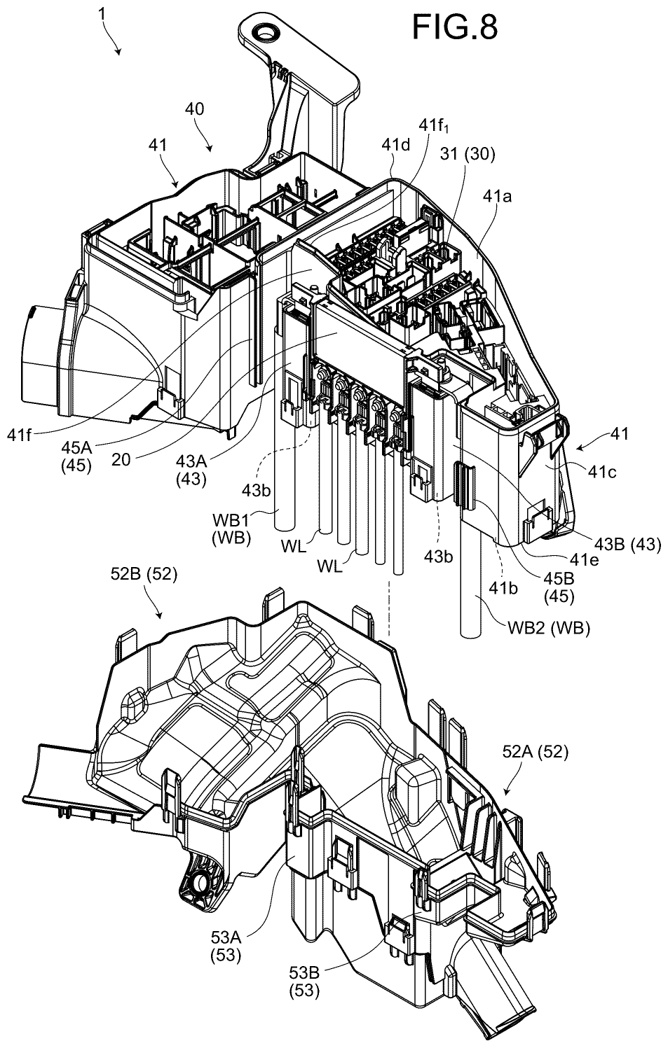

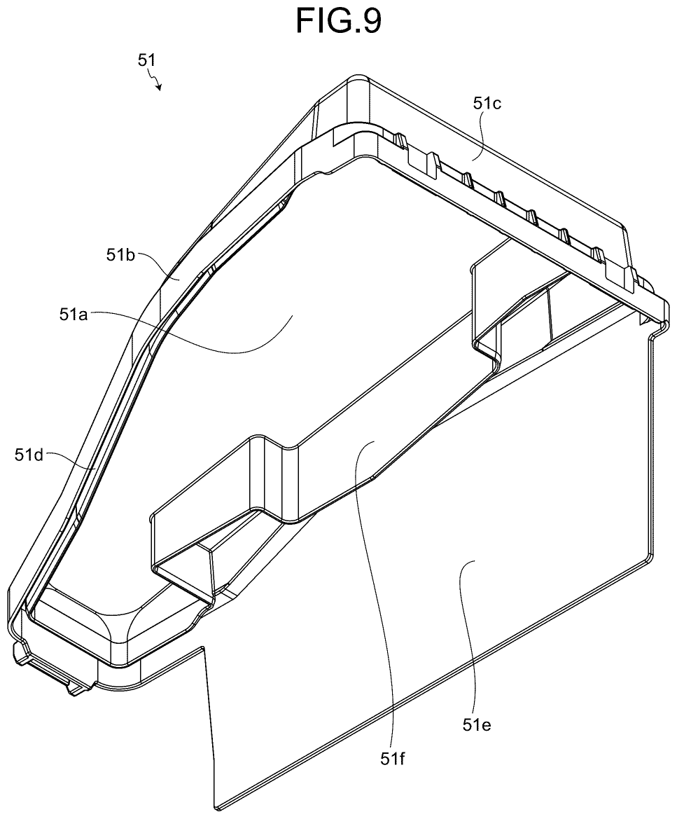

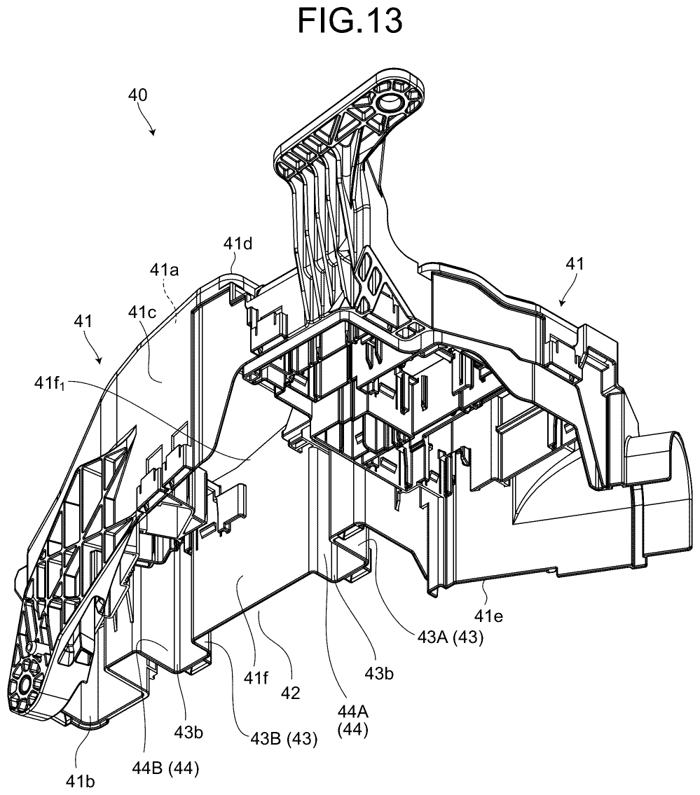

One embodiment of an electrical connection box according to the present invention will be described with reference to FIGS. 1 to 15.

Reference Numeral 1 illustrated in FIGS. 1 to 6 indicates the electrical connection box according to the present embodiment. An electrical connection box 1 is mounted on a vehicle such as an automobile, and is interposed between an external power supply B such as a secondary battery in the vehicle and an external load L such as a power distribution target (for example, auxiliary devices to be subjected to power supply) to supply power of the external power supply B to the external load L (FIG. 1).

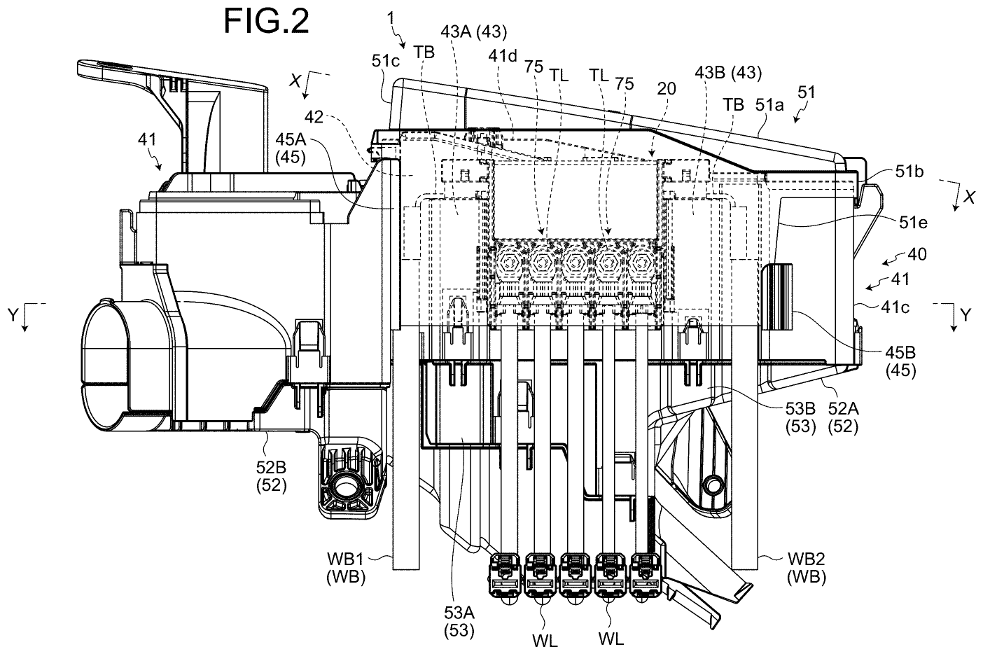

The electrical connection box 1 includes an electronic component 10 such as a relay or a fuse (FIG. 2), and the electronic component 10 is interposed between the external power supply B and the external load L. Further, the electrical connection box 1 includes a circuit branching component 20 interposed between the external power supply B and the external load L (FIGS. 1 to 6). The circuit branching component 20 is a component for distributing power from the external power supply B to a plurality of external loads L. The electrical connection box 1 includes a plurality of electronic components 10 and at least one circuit branching component 20.

The electrical connection box 1 includes a block 30 that holds the electronic component 10 and a frame 40 including a tubular portion 41 that houses and holds the block 30 therein and includes a tubular wall 41c having openings (openings 41a and 41b) at both ends (FIGS. 1 to 8). The electrical connection box 1 includes a cover member (hereinafter, referred to as a “first cover member”) 51 that is fitted to an opening peripheral edge portion (hereinafter, referred to as a “first opening peripheral edge portion”) 41d of a peripheral edge of one opening 41a of the tubular portion 41 and closes the one opening 41a of the tubular portion 41, and a cover member (hereinafter, referred to as a “second cover member”) 52 that is fitted to an opening peripheral edge portion (hereinafter, referred to as a “second opening peripheral edge portion”) 41e of a peripheral edge of the other opening 41b of the tubular portion 41 and closes the other opening 41b of the tubular portion 41 (FIGS. 1, 2, 4, 6, 8, and 9). The block 30, the frame 40, the first cover member 51, and the second cover member 52 are formed of an insulating material such as a synthetic resin.

In the electrical connection box 1, a housing is formed by the frame 40, the first cover member 51, and the second cover member 52, and an electric wire (not illustrated) electrically connected to the electronic component 10 is routed in the housing and drawn out from an opening to the outside of the housing.

In the frame 40, the block 30 is inserted into the tubular portion 41 through the other opening 41b. In a case where the frame 40 is implemented by one tubular portion 41, the entire outer wall forming an outer frame is formed by the tubular wall 41c of the tubular portion 41. In addition, in a case where the frame 40 is implemented by a combination of a plurality of tubular portions 41 with the one openings 41a having the same opening direction and the other openings 41b having the same opening direction, the outer wall forming the outer frame is formed by a combination of parts of the tubular walls 41c of the plurality of tubular portions 41. That is, the outer wall forming the outer frame of the frame 40 is entirely or partially formed by the tubular wall 41c of the tubular portion 41.

The frame 40 is installed with the one opening 41a of the tubular portion 41 facing vertically upward. The frame 40 illustrated here is a combination of two tubular portions 41, and is mounted on the vehicle with the one opening 41a facing an upper side of the vehicle. The first cover member 51 illustrated here is provided for each of the tubular portions 41. In addition, the second cover member 52 illustrated here is divided into a first divided cover 52A and a second divided cover 52B assembled with each other, and closes the other opening 41b of each of the two tubular portions 41 in a form in which the first divided cover 52A and the second divided cover 52B are assembled (FIGS. 1, 2, 6, and 8).

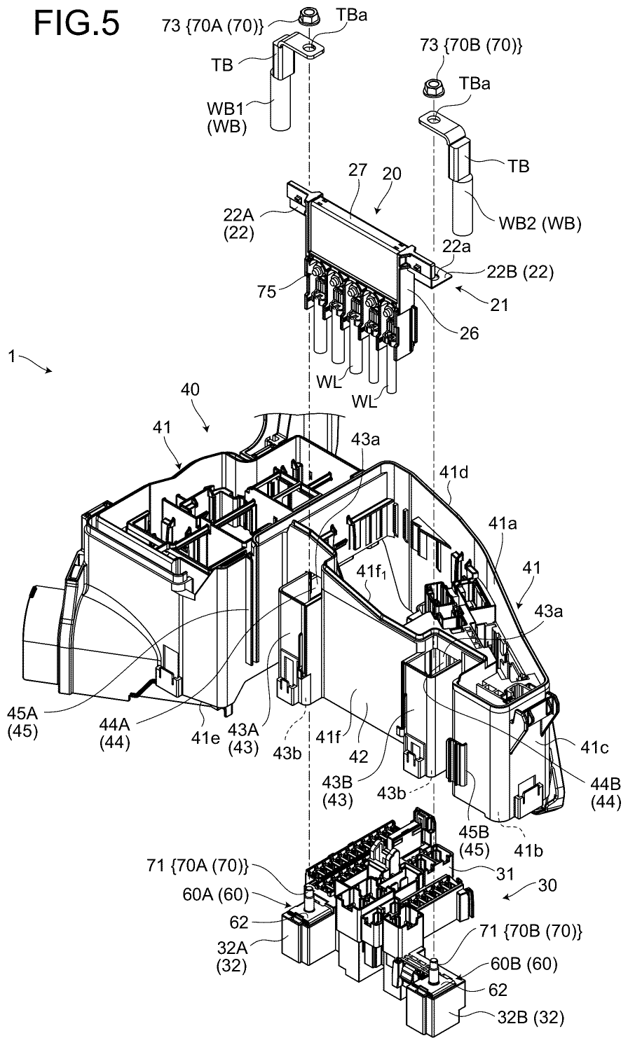

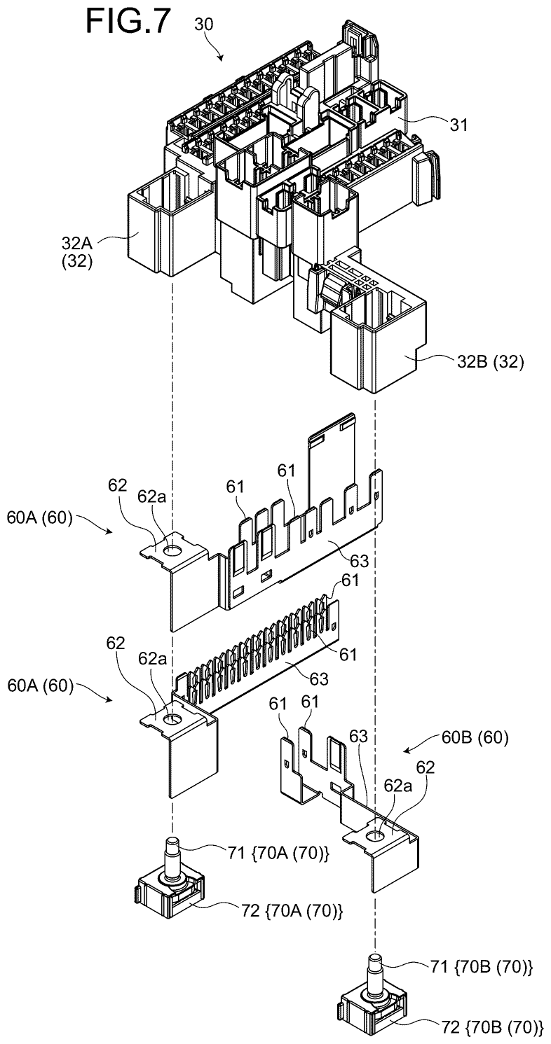

The electrical connection box 1 includes an internal conductive member 60 that electrically connects the electronic component 10 to the external power supply B and is held by the block 30 together with the electronic component 10 (FIGS. 5 and 7). The internal conductive member 60 includes a first electrical connection portion 61 that is physically and electrically connected to the electronic component 10 in the tubular portion 41 (FIG. 7). The first electrical connection portion 61 is provided for each electronic component 10. In addition, the internal conductive member 60 includes a second electrical connection portion 62 electrically connected to the external power supply B (FIGS. 5 and 7). In the internal conductive member 60, the plurality of first electrical connection portions 61 and the second electrical connection portion 62 are connected by a coupling portion 63 (FIG. 7). The internal conductive member 60 has a shape in which the coupling portion 63 extends to an outside of the tubular portion 41, and the second electrical connection portion 62 is coupled to an end of the coupling portion 63 that extends outside the frame 40. That is, the second electrical connection portion 62 is disposed outside the frame 40 and outside the tubular portion 41.

The internal conductive member 60 is a so-called bus bar, and is formed in a plate shape using a metal plate as a base material, for example. The block 30 includes a block body 31 that holds the electronic component 10 and the internal conductive member 60 in the tubular portion 41 (FIGS. 1 and 3 to 8).

The electrical connection box 1 may include the frame 40 integrated with the block 30. The frame 40 includes the tubular wall 41c having an opening 41a at least at one end, and includes a tubular portion 41 that houses and holds the electronic component 10 and the internal conductive member 60 therein. For example, the electrical connection box 1 includes the first cover member 51 and the second cover member 52 as in the above example as long as the frame 40 includes the tubular portion 41 including the tubular wall 41c having the openings (the openings 41a and 41b) at both ends. On the other hand, the electrical connection box 1 includes only the first cover member 51 in a case where the frame 40 includes the tubular portion 41 (that is, the tubular portion 41 of which the opening 41b is closed) including the tubular wall 41c having only the opening 41a.

The circuit branching component 20 is disposed outside the frame 40 and outside the tubular portion 41. The circuit branching component 20 includes a conductive circuit branching member 21 interposed between the external power supply B and the external load L (FIGS. 5, 10, and 11).

Here, the circuit branching component 20 includes at least a power supply connection portion 22 and a load connection portion 23 described below. The circuit branching component 20 includes a coupling portion 25 described below that electrically connects the power supply connection portion 22 and a plurality of load connection portions 23. However, the circuit branching component 20 illustrated here includes, in addition to the power supply connection portion 22 and the load connection portion 23, a fusible portion 24 described below for cutting off an overcurrent between the external power supply B and the external load L, and accordingly, includes the coupling portion 25 described below. That is, here, as an example of the circuit branching component 20, a circuit protection component for cutting off an overcurrent between the external power supply B and the external load L is exemplified. Therefore, the circuit branching component (circuit protection component) 20 illustrated here includes a conductive circuit protection member interposed between the external power supply B and the external load L as the circuit branching member 21.

The circuit branching member (circuit protection member) 21 includes the power supply connection portion 22 that is electrically connected to a power-supply-side electric wire WB electrically connected to the external power supply B and is physically and electrically connected to the second electrical connection portion 62 of the internal conductive member 60 (FIGS. 5, 10, and 11).

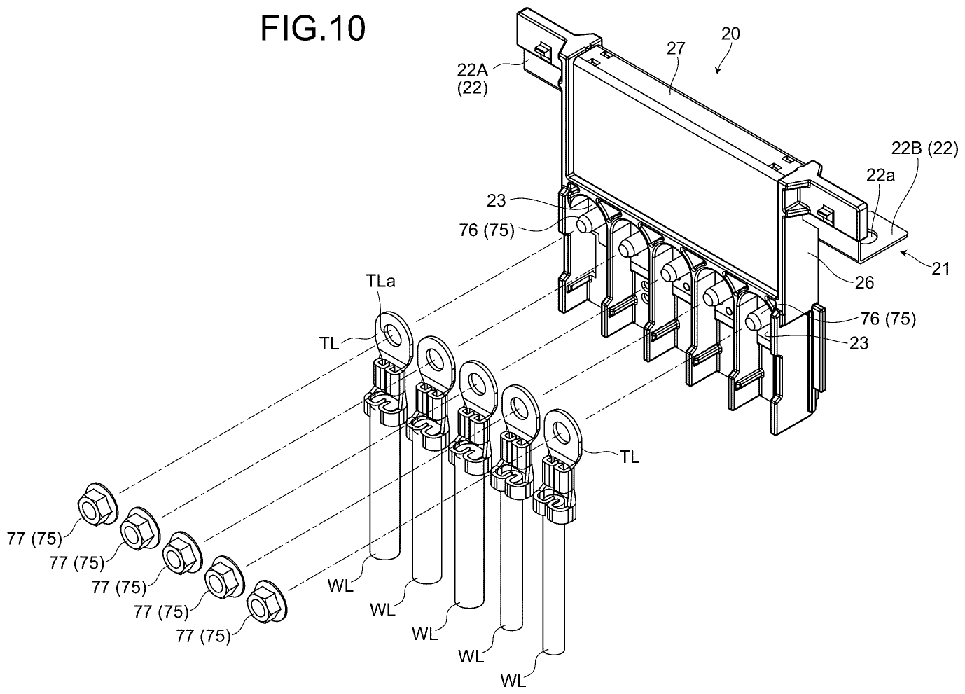

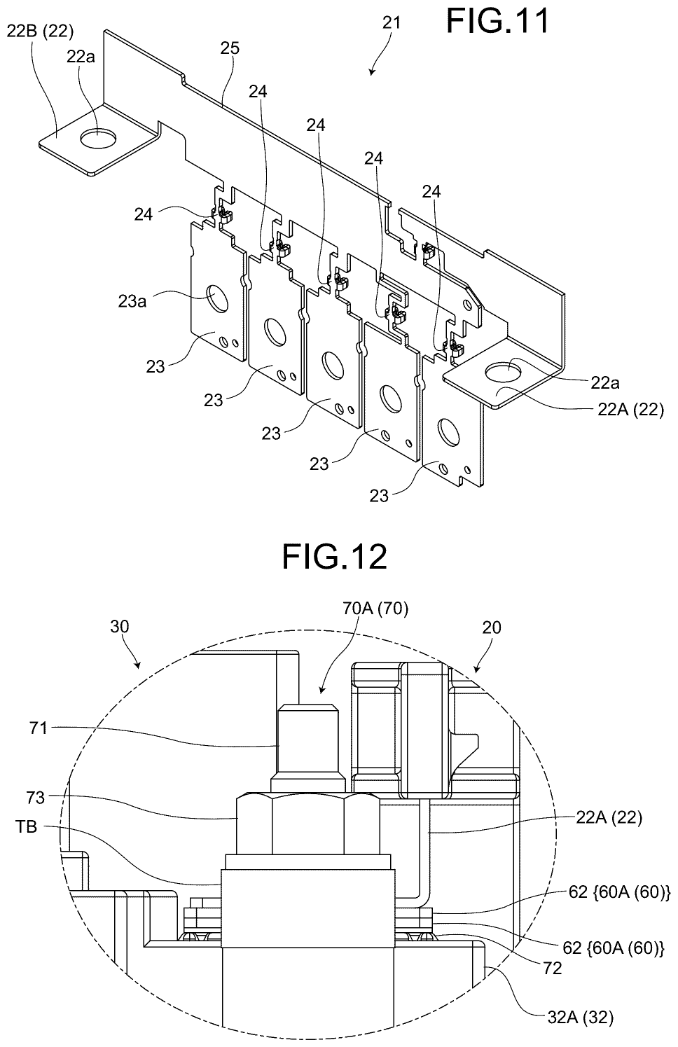

In addition, the circuit branching member (circuit protection member) 21 includes the load connection portion 23 that is electrically connected to a load-side electric wire WL electrically connected to the external load L, and the fusible portion 24 that is interposed between the power supply connection portion 22 and the load connection portion 23 and is fused when an overcurrent flows (FIGS. 10 and 11). In the circuit branching member (circuit protection member) 21, the load connection portion 23 and the fusible portion 24 are provided for each external load L. The circuit branching member (circuit protection member) 21 includes the coupling portion 25 that couples the power supply connection portion 22 and the fusible portion 24 (FIG. 11). The power supply connection portion 22 and the fusible portion 24 for each external load L are connected to the coupling portion 25.

The circuit branching member (circuit protection member) 21 is a so-called bus bar, and is formed in a plate shape using a metal plate as a base material, for example. In the circuit branching component (circuit protection component) 20, a resin portion 26 is integrally formed with the circuit branching member (circuit protection member) 21 by using a synthetic resin material in a state where the power supply connection portion 22, the load connection portion 23, and the fusible portion 24 are exposed (FIGS. 5 and 10). Then, in the circuit branching component (circuit protection component) 20, a transparent resin cover 27 that is made of a synthetic resin material and covers the exposed fusible portion 24 is assembled to the resin portion 26 (FIGS. 5 and 10).

In the circuit branching component (circuit protection component) 20, the power supply connection portion 22 is disposed more adjacent to the first opening peripheral edge portion 41d than the load connection portion 23 in a tube axis direction of the tubular portion 41 (FIGS. 5 and 10).

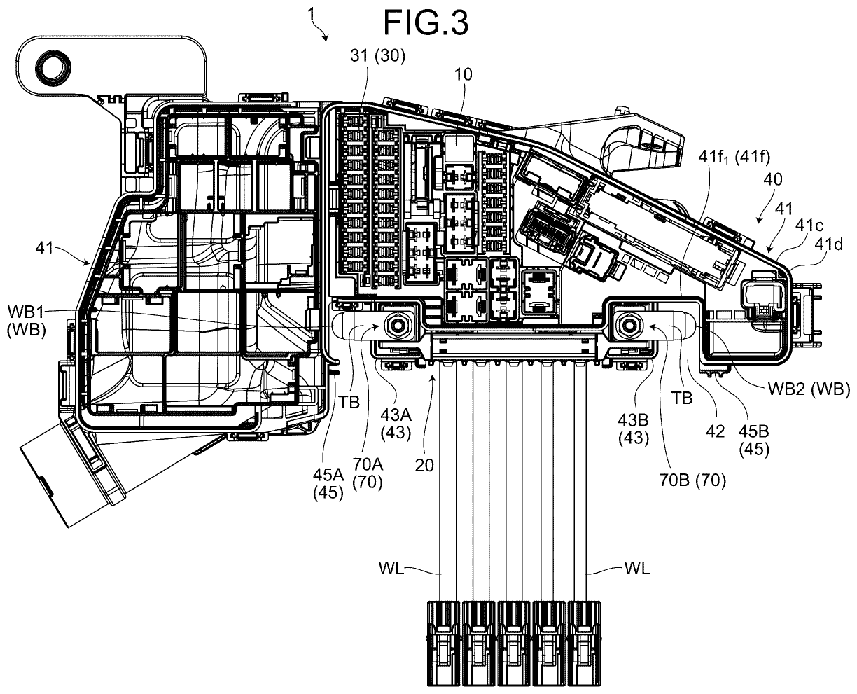

The electrical connection box 1 includes a power-supply-side electrical connection structure 70 that electrically connects the power-supply-side electric wire WB, the second electrical connection portion 62 of the internal conductive member 60, and the power supply connection portion 22 of the circuit branching member (circuit protection member) 21 to each other (FIGS. 3 to 5, 7, and 12). A power-supply-side terminal fitting TB is attached to a terminal of the power-supply-side electric wire WB (FIGS. 2 to 5). Therefore, the power-supply-side electrical connection structure 70 physically and electrically connects the power-supply-side terminal fitting TB, the second electrical connection portion 62 of the internal conductive member 60, and the power supply connection portion 22 of the circuit branching member (circuit protection member) 21 to each other.

The power-supply-side electrical connection structure 70 illustrated here includes a male screw member 71, a screw holding member 72 that holds the male screw member 71 in a state where a male screw portion is exposed, and a female screw member 73 to be screwed to the male screw portion of the male screw member 71 (FIGS. 5, 7, and 12). In the power-supply-side electrical connection structure 70, the male screw portion of the male screw member 71 is inserted into through-holes TBa, 62a, and 22a provided in the power-supply-side terminal fitting TB, the second electrical connection portion 62 of the internal conductive member 60, and the power supply connection portion 22 of the circuit branching member (circuit protection member) 21, respectively, and the female screw member 73 is screwed to the male screw portion, whereby the power-supply-side terminal fitting TB, the second electrical connection portion 62 of the internal conductive member 60, and the power supply connection portion 22 of the circuit branching member (circuit protection member) 21 are fastened and fixed together (FIGS. 5 and 7).

Here, in the power-supply-side electrical connection structure 70, the male screw member 71 is disposed such that a screw axis of the male screw portion is aligned with a vertical direction (that is, a top-bottom direction of the vehicle) and the male screw portion protrudes from the screw holding member 72 vertically upward (that is, toward the upper side of the vehicle).

In addition, the electrical connection box 1 includes a load-side electrical connection structure 75 that electrically connects the load-side electric wire WL and the load connection portion 23 of the circuit branching member (circuit protection member) 21 to each other (FIGS. 2, 5, and 10). A load-side terminal fitting TL is attached to a terminal of the load-side electric wire WL (FIGS. 2 and 10). Therefore, the load-side electrical connection structure 75 physically and electrically connects the load-side terminal fitting TL and the load connection portion 23 of the circuit branching member (circuit protection member) 21 to each other.

The load-side electrical connection structure 75 illustrated here includes a male screw member 76 and a female screw member 77 to be screwed to a male screw portion of the male screw member 76 (FIG. 10). The resin portion 26 is integrally formed with the male screw member 76 in a state where the male screw portion of the male screw member 76 is inserted into a through-hole 23a (FIG. 11) of the load connection portion 23 of the circuit branching member (circuit protection member) 21 and the male screw portion is exposed. In the load-side electrical connection structure 75, the male screw portion of the male screw member 76 is inserted into a through-hole TLa provided in the load-side terminal fitting TL, and the female screw member 77 is screwed to the male screw portion, whereby the load-side terminal fitting TL and the load connection portion 23 of the circuit branching member (circuit protection member) 21 are fastened and fixed together (FIG. 10).

Here, in the load-side electrical connection structure 75, the male screw member 76 is disposed such that the male screw portion protrudes toward a side opposite to the tubular wall 41c of the tubular portion 41. In this example, the male screw member 76 is disposed such that a screw axis of the male screw portion is aligned with a direction orthogonal to the vertical direction (that is, the top-bottom direction of the vehicle), and the male screw portion protrudes toward the side opposite to the tubular wall 41c of the tubular portion 41.

Specifically, the circuit branching component (circuit protection component) 20 is disposed outside the frame 40 as follows.

The frame 40 has a recess 42 which is a portion of the outer wall forming the outer frame that is recessed toward the inside of the tubular portion 41 and in which the circuit branching component (circuit protection component) 20 is disposed (FIGS. 2 to 5 and 13). The recess 42 desirably has a volume equal to or larger than a size of the circuit branching component (circuit protection component) 20 and can house the circuit branching component (circuit protection component) 20 such that the circuit branching component (circuit protection component) 20 does not protrude. For example, the tubular wall 41c of the tubular portion 41 has a facing wall body 41f disposed to face the circuit branching component (circuit protection component) 20 outside the tubular portion 41. The recess 42 is formed by making the facing wall body 41f be recessed toward the inside of the tubular portion 41.

In addition, the frame 40 includes a sub tubular portion 43 having an opening 43a opened in the same direction as the one opening 41a of the tubular portion 41 and bulging from the tubular wall 41c of the tubular portion 41 toward an outside of the frame 40 outside the tubular portion 41 (FIGS. 1 to 5, 8, and 13). The sub tubular portion 43 bulges from the facing wall body 41f toward the outside of the frame 40 outside the tubular portion 41. The sub tubular portion 43 illustrated here is formed as a tubular body having openings (openings 43a and 43b) at both ends and bulging from the facing wall body 41f at the recess 42 of the frame 40. Therefore, in the sub tubular portion 43, one opening 43a is disposed on a side of the one opening 41a of the tubular portion 41 (that is, on a side of the first opening peripheral edge portion 41d), and the other opening 43b is disposed on a side of the other opening 41b of the tubular portion 41 (that is, on a side of the second opening peripheral edge portion 41e).

The power-supply-side electrical connection structure 70 is provided in the sub tubular portion 43. In the sub tubular portion 43, the screw holding member 72 of the power-supply-side electrical connection structure 70 is housed in the sub tubular portion 43, and the male screw portion of the male screw member 71 in the power-supply-side electrical connection structure 70 protrudes from the one opening 43a. Therefore, in the second electrical connection portion 62 of the internal conductive member 60, the male screw portion of the male screw member 71 protruding from the one opening 43a of the sub tubular portion 43 is inserted into the through-hole 62a on a side more adjacent to the one opening 41a of the tubular portion 41 than the one opening 43a. Therefore, the tubular wall 41c of the tubular portion 41 has a notch 44 through which the inside of the tubular portion 41 communicates with the inside of the sub tubular portion 43, and the second electrical connection portion 62 of the internal conductive member 60 protrudes toward the outside of the frame 40 outside the tubular portion 41 (FIG. 5). The notch 44 is a notch formed by cutting out the tubular wall 41c of the tubular portion 41 from an end portion on a side of the other opening 41b toward the one opening 41a, and extends to the one opening 41a of the tubular portion 41 beyond the one opening 43a of the sub tubular portion 43. Here, the notch 44 is formed in the facing wall body 41f.

The block 30 includes a protruding block portion 32 that protrudes from the notch 44 toward the outside of the tubular portion 41 and is housed in the sub tubular portion 43 (FIGS. 5 and 7). The screw holding member 72 is assembled to the protruding block portion 32, whereby the power-supply-side electrical connection structure 70 is held.

In the electrical connection box 1, in a state where the internal conductive member 60 is held by the block body 31 and the power-supply-side electrical connection structure 70 is held by the protruding block portion 32, the male screw portion of the male screw member 71 of the power-supply-side electrical connection structure 70 is inserted into the through-hole 62a of the second electrical connection portion 62 of the internal conductive member 60. In the electrical connection box 1, the block body 31 holding the internal conductive member 60 is inserted into the tubular portion 41 through the other opening 41b, and the protruding block portion 32 holding the power-supply-side electrical connection structure 70 is inserted into the sub tubular portion 43 through the other opening 43b together with the second electrical connection portion 62 of the internal conductive member 60. In the electrical connection box 1, the protruding block portion 32 and the power-supply-side electrical connection structure 70 are housed in the sub tubular portion 43 in a state where the second electrical connection portion 62 of the internal conductive member 60 is pulled out from the one opening 43a of the sub tubular portion 43 together with the male screw portion of the male screw member 71.

In the electrical connection box 1, the male screw portion of the male screw member 71 is inserted into the through-hole 22a to assemble the power supply connection portion 22 of the circuit branching member (circuit protection member) 21 to the power-supply-side electrical connection structure 70, and further, the male screw portion of the male screw member 71 is inserted into the through-hole TBa to assemble the power-supply-side terminal fitting TB to the power-supply-side electrical connection structure 70. In the electrical connection box 1, the female screw member 73 is screwed to the male screw portion of the male screw member 71 to fasten and fix the power-supply-side terminal fitting TB, the second electrical connection portion 62 of the internal conductive member 60, and the power supply connection portion 22 of the circuit branching member (circuit protection member) 21 together. In the electrical connection box 1, the power-supply-side terminal fitting TB and the circuit branching component (circuit protection component) 20 are assembled to the block 30 via the power-supply-side electrical connection structure 70.

The one opening 43a of the sub tubular portion 43 is covered with the first cover member 51 assembled to the frame 40 together with the power-supply-side terminal fitting TB, the second electrical connection portion 62 of the internal conductive member 60, the power supply connection portion 22 of the circuit branching member (circuit protection member) 21, and the power-supply-side electrical connection structure 70, and is housed in the first cover member 51. The first cover member 51 covers the recess 42 of the frame 40, and houses the circuit branching component (circuit protection component) 20 in the recess 42 in a space between the recess 42 and the first cover member 51.

Specifically, the first cover member 51 includes a cover main body 51a that is disposed to face the one opening 41a of the tubular portion 41, an annular outer peripheral wall body 51b that covers the first opening peripheral edge portion 41d from the outside of the tubular portion 41, a closing wall body 51c that closes a gap between the cover main body 51a and the outer peripheral wall body 51b, an annular inner peripheral wall body 51d that is disposed at an interval from the outer peripheral wall body 51b on an inner side of the outer peripheral wall body 51b and is fitted to the first opening peripheral edge portion 41d, and a waterproof cover wall body 51e that suppresses water splashing onto the circuit branching component (circuit protection component) 20.

In the first cover member 51, a gap between a peripheral edge portion of the cover main body 51a and a peripheral edge portion of one opening of the outer peripheral wall body 51b that is adjacent to the cover main body 51a is closed by the closing wall body 51c. Therefore, in the first cover member 51, the cover main body 51a, the outer peripheral wall body 51b, and the closing wall body 51c form an internal space opened on a side of the outer peripheral wall body 51b that is opposite to the cover main body 51a.

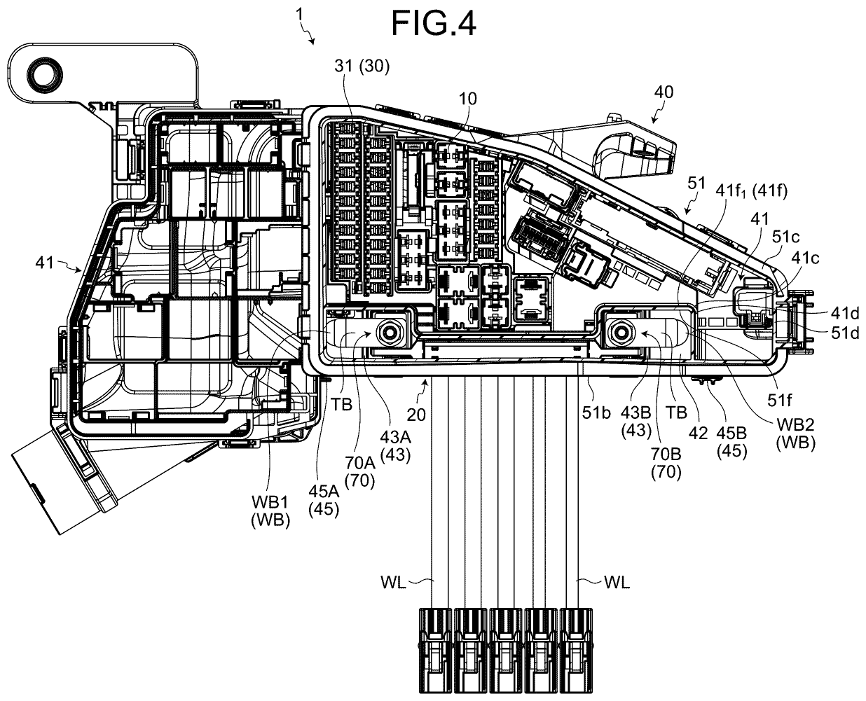

The outer peripheral wall body 51b is disposed to face the facing wall body 41f at an interval corresponding to at least a space where the circuit branching component (circuit protection component) 20 is present (FIG. 4). Therefore, in the first cover member 51, the cover main body 51a, the outer peripheral wall body 51b, and the closing wall body 51c can cover the circuit branching component (circuit protection component) 20 from a one opening 41a side outside the tubular portion 41. Therefore, the first cover member 51 can suppress splashing of water onto the circuit branching component (circuit protection component) 20 from vertically above (from the upper side of the vehicle). Here, the cover main body 51a, the outer peripheral wall body 51b, and the closing wall body 51c cover the one opening 43a of the sub tubular portion 43 and the power-supply-side electric wire WB together with the circuit branching component (circuit protection component) 20 from the one opening 41a side outside the tubular portion 41. Therefore, the first cover member 51 can cover the circuit branching component (circuit protection component) 20, the power-supply-side terminal fitting TB, the second electrical connection portion 62 of the internal conductive member 60, and the power-supply-side electrical connection structure 70 from the one opening 41a side outside the tubular portion 41. Therefore, the first cover member 51 can suppress splashing of water onto the circuit branching component (circuit protection component) 20, the power-supply-side terminal fitting TB, and the like from vertically above (from the upper side of the vehicle).

The inner peripheral wall body 51d is disposed in an internal space formed by the cover main body 51a, the outer peripheral wall body 51b, and the closing wall body 51c. The inner peripheral wall body 51d is an annular wall body extending to the cover main body 51a and connected to the cover main body 51a. In the first cover member 51, the cover main body 51a and the inner peripheral wall body 51d form an internal space opened on a side of the inner peripheral wall body 51d that is opposite to the cover main body 51a. That is, the inner peripheral wall body 51d forms a partition wall that divides the internal space formed by the cover main body 51a, the outer peripheral wall body 51b, and the closing wall body 51c by two.

The inner peripheral wall body 51d has a waterproof wall portion 51f that is fitted to a peripheral edge portion 41f1 of the facing wall body 41f that is on the side of the one opening 41a from the outside of the tubular portion 41 and covers the peripheral edge portion 41f1 of the facing wall body 41f that is a part of the first opening peripheral edge portion 41d from the outside of the tubular portion 41 (FIGS. 4, 6, and 9).

The waterproof cover wall body 51e protrudes from the outer peripheral wall body 51b to a position where the circuit branching component (circuit protection component) 20 is covered between the waterproof cover wall body 51e and the facing wall body 41f (FIGS. 1 and 2). The waterproof cover wall body 51e protrudes from the outer peripheral wall body 51b toward the other opening 41b of the tubular portion 41 in the tube axis direction of the tubular portion 41, and is disposed to face the facing wall body 41f at an interval. As a result, the first cover member 51 can cover the circuit branching component (circuit protection component) 20 from the one opening 41a side outside the tubular portion 41 by the cover main body 51a, the outer peripheral wall body 51b, and the closing wall body 51c, and cover the circuit branching component (circuit protection component) 20 from a facing wall body 41f side (that is, a lateral side of the frame 40) outside the tubular portion 41 by the waterproof cover wall body 51e. Therefore, the first cover member 51 can suppress splashing of water onto the circuit branching component (circuit protection component) 20 from vertically above (from the upper side of the vehicle), and can suppress splashing of water onto the circuit branching component (circuit protection component) 20 from a front side of the vehicle, a rear side of the vehicle, a lateral side of the vehicle, or the like.

Further, the waterproof cover wall body 51e is formed in a shape that covers the sub tubular portion 43 and the power-supply-side electric wire WB together with the circuit branching component (circuit protection component) 20 (FIGS. 1 and 2). Therefore, the first cover member 51 can cover the circuit branching component (circuit protection component) 20, the power-supply-side terminal fitting TB, the second electrical connection portion 62 of the internal conductive member 60, and the power-supply-side electrical connection structure 70 from the one opening 41a side outside the tubular portion 41 by the cover main body 51a, the outer peripheral wall body 51b, and the closing wall body 51c, and cover the circuit branching component (circuit protection component) 20, the power-supply-side terminal fitting TB, the second electrical connection portion 62 of the internal conductive member 60, and the power-supply-side electrical connection structure 70 from the facing wall body 41f side (the lateral side of the frame 40) outside the tubular portion 41 by the waterproof cover wall body 51e. Therefore, the first cover member 51 can suppress splashing of water onto the circuit branching component (circuit protection component) 20, the power-supply-side terminal fitting TB, and the like from vertically above (from the upper side of the vehicle), and can suppress splashing of water onto the circuit branching component (circuit protection component) 20, the power-supply-side terminal fitting TB, and the like from the front side of the vehicle, the rear side of the vehicle, the lateral side of the vehicle, and the like.

In addition, the first cover member 51 covers the entire circuit branching component (circuit protection component) 20 from the facing wall body 41f side (the lateral side of the frame 40) outside the tubular portion 41 by the waterproof cover wall body 51e. That is, the waterproof cover wall body 51e covers the circuit branching component (circuit protection component) 20 from an end portion of the tubular portion 41 that is adjacent to the one opening 41a to an end portion that is adjacent to the other opening 41b. Therefore, the waterproof cover wall body 51e makes it difficult for water splashed up from vertically below (from the lower side of the vehicle) to reach an end portion of the circuit branching component (circuit protection component) 20 that is adjacent to the other opening 41b, and can suppress water from reaching the power-supply-side electrical connection structure 70 and the load-side electrical connection structure 75.

As described above, the first cover member 51 can ensure waterproofness for the circuit branching component (circuit protection component) 20, the power-supply-side electrical connection structure 70, and the like outside the tubular portion 41.

Here, the waterproof cover wall body 51e is formed as a cantilevered flat plate having an outer peripheral wall body 51b side end portion as a fixed end and the other opening 41b side end portion protruding from the outer peripheral wall body 51b as a free end. Therefore, when the waterproof cover wall body 51e is deformed in a direction away from the circuit branching component (circuit protection component) 20 and a distance from the facing wall body 41f is increased at the other opening 41b side end portion, water easily enters through the gap.

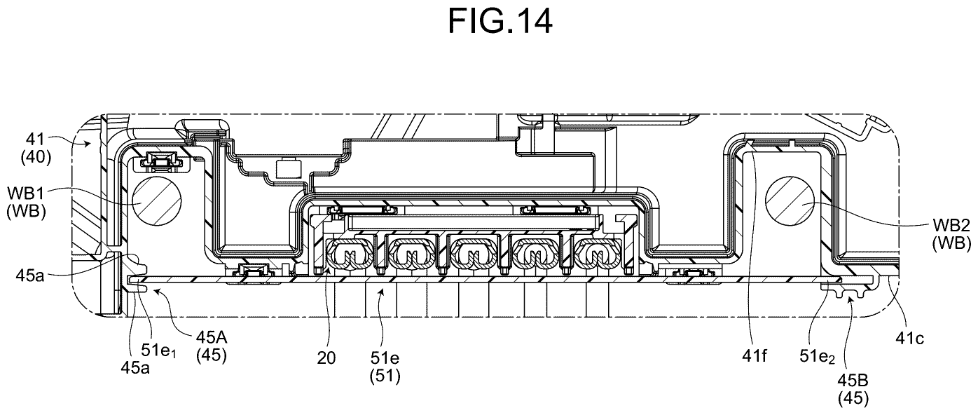

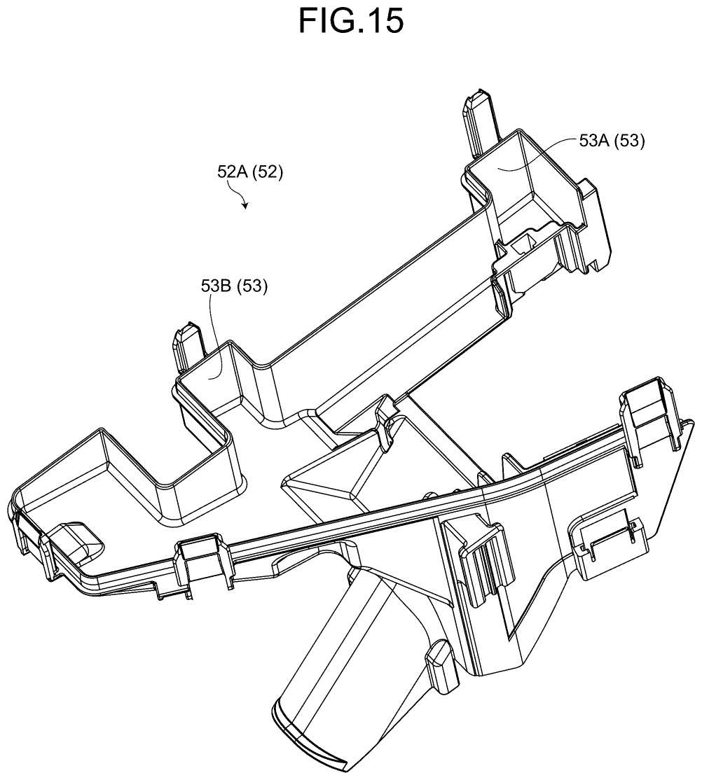

Therefore, the frame 40 includes at least two cover deformation suppressing portions 45 into which a peripheral edge of the waterproof cover wall body 51e is fitted to suppress deformation of the waterproof cover wall body 51e in a direction away from the circuit branching component (circuit protection component) 20 (FIGS. 1 to 6, 8, and 14). The waterproof cover wall body 51e has two side end portions 51e₁ and 51e₂ along a protruding direction from the outer peripheral wall body 51b (FIG. 14). Here, as the cover deformation suppressing portions 45, a first cover deformation suppressing portion 45A that locks an outer wall surface (a wall surface on a side opposite to the circuit branching component (circuit protection component) 20) at one side end portion 51e₁ of the waterproof cover wall body 51e and a second cover deformation suppressing portion 45B that locks an outer wall surface (the wall surface on the side opposite to the circuit branching component (circuit protection component) 20) at the other side end portion 51e₂ of the waterproof cover wall body 51e are provided in a protruding state on the tubular wall 41c of the tubular portion 41.

The first cover deformation suppressing portion 45A includes a pair of protruding portions 45a and 45a protruding from the tubular wall 41c outside the tubular portion 41 and extending in a direction in which the first cover member 51 is assembled to the tubular portion 41. The pair of protruding portions 45a and 45a is arranged with a gap larger than a plate thickness of the waterproof cover wall body 51e therebetween, and the one side end portion 51e₁ of the waterproof cover wall body 51e enters the gap therebetween. In the first cover deformation suppressing portion 45A, the one side end portion 51e₁ of the waterproof cover wall body 51e is inserted between the pair of protruding portions 45a and 45a along with an operation of assembling the first cover member 51 to the tubular portion 41. In the first cover deformation suppressing portion 45A, one protruding portion 45a disposed to face an outer wall surface of the one side end portion 51e₁ of the waterproof cover wall body 51e locks the outer wall surface.

The second cover deformation suppressing portion 45B is a protruding body protruding from the tubular wall 41c outside the tubular portion 41, is formed as an L-shaped protruding body having an L-shaped cross section orthogonal to the direction in which the first cover member 51 is assembled to the tubular portion 41, and locks an outer wall surface of the other side end portion 51e₂ of the waterproof cover wall body 51e.

Here, the first cover deformation suppressing portion 45A locks the one side end portion 51e₁ of the waterproof cover wall body 51e from an outer wall surface side, and the second cover deformation suppressing portion 45B locks the other side end portion 51e₂ of the waterproof cover wall body 51e from the outer wall surface side, thereby suppressing deformation of the waterproof cover wall body 51e in a direction away from the circuit branching component (circuit protection component) 20. Therefore, the first cover member 51 can keep preventing water from reaching the power-supply-side electrical connection structure 70 or the load-side electrical connection structure 75 by splashing up from vertically below (from the lower side of the vehicle) by the waterproof cover wall body 51e.

The other opening 43b of the sub tubular portion 43 is closed by a closing portion 53 provided in the second cover member 52 assembled to the frame 40 so as not to be exposed to the outside of the frame 40 (FIGS. 1, 2, 6, 8, and 15).

In the electrical connection box 1, all core wires of the power-supply-side electric wire WB and the load-side electric wire WL may be formed of copper or a copper alloy. However, in order to reduce weights of the power-supply-side electric wire WB and the load-side electric wire WL, at least one core wire thereof is desirably formed of aluminum or an aluminum alloy. For example, the power-supply-side electric wire WB and the load-side electric wire WL may be formed such that all the core wires are formed of aluminum or an aluminum alloy, or at least one core wire may be formed of aluminum or an aluminum alloy, and the remaining core wires may be formed of copper or a copper alloy.

In a case where the core wires of the power-supply-side electric wire WB and the load-side electric wire WL are formed of aluminum or an aluminum alloy, the weights of the power-supply-side electric wire WB and the load-side electric wire WL can be reduced as compared with a case where the core wires are formed of copper or a copper alloy. However, in this case, the power-supply-side electric wire WB and the load-side electric wire WL become thick and hard for a large current, and are difficult to bend. However, in the electrical connection box 1, the circuit branching component (circuit protection component) 20 is disposed outside the frame 40 and outside the tubular portion 41, and such a power-supply-side electric wire WB and a load-side electric wire WL that are difficult to bend are routed outside the frame 40. Therefore, the electrical connection box 1 can suppress an overload applied to the periphery in the housing due to the power-supply-side electric wire WB or the like, and can improve a housing property for other electric wires in the tubular portion 41.

Specifically, the electrical connection box 1 illustrated here includes, as the internal conductive members 60, a first internal conductive member 60A and a second internal conductive member 60B, and the first internal conductive member 60A and the second internal conductive member 60B are held by the block 30 (FIGS. 5 and 7). Here, two types of first internal conductive members 60A are provided as the internal conductive members 60.

The circuit branching member (circuit protection member) 21 illustrated here includes a first power supply connection portion 22A and a second power supply connection portion 22B as the power supply connection portions 22, and the first power supply connection portion 22A and the second power supply connection portion 22B are electrically connected to a first power-supply-side electric wire WB1 and a second power-supply-side electric wire WB2 as the power-supply-side electric wires WB, respectively (FIGS. 5, 10, and 11). In the circuit branching member (circuit protection member) 21, the first power supply connection portion 22A and the second power supply connection portion 22B are coupled by the coupling portion 25, and the fusible portion 24 is coupled to the first power supply connection portion 22A and the second power supply connection portion 22B via the coupling portion 25. That is, the fusible portion 24 is interposed between the first power supply connection portion 22A and the load connection portion 23, and is interposed between the second power supply connection portion 22B and the load connection portion 23.

The first power-supply-side electric wire WB1 is interposed between the first power supply connection portion 22A and the external power supply B when viewed from the circuit branching member (circuit protection member) 21, and electrically connects the first power supply connection portion 22A to the external power supply B. The second power-supply-side electric wire WB2 is electrically connected to an external electric component P such as an alternator or a DC-DC converter disposed outside the housing, and is electrically connected to the external power supply B via the circuit branching member (circuit protection member) 21 and the first power-supply-side electric wire WB1. That is, the second power-supply-side electric wire WB2 electrically connects the external electric component P to the external power supply B via the circuit branching member (circuit protection member) 21 and the first power-supply-side electric wire WB1.

The first power supply connection portion 22A electrically connects the first power-supply-side electric wire WB1 and physically and electrically connects the second electrical connection portion 62 of the first internal conductive member 60A. The electrical connection box 1 includes a first power-supply-side electrical connection structure 70A as the power-supply-side electrical connection structure 70 that electrically connects the first power-supply-side electric wire WB1, the second electrical connection portion 62 of the first internal conductive member 60A, and the first power supply connection portion 22A of the circuit branching member (circuit protection member) 21 to each other (FIGS. 2 to 5, 7, and 12). In the first power-supply-side electrical connection structure 70A, the male screw portion of the male screw member 71 is inserted into each of the through-holes TBa, 62a, and 22a of the power-supply-side terminal fitting TB of the terminal of the first power-supply-side electric wire WB1, the second electrical connection portion 62 of the first internal conductive member 60A, and the first power supply connection portion 22A of the circuit branching member (circuit protection member) 21, and the female screw member 73 is screwed to the male screw portion, whereby the power-supply-side terminal fitting TB, the second electrical connection portion 62 of the first internal conductive member 60A, and the first power supply connection portion 22A of the circuit branching member (circuit protection member) 21 are fastened and fixed together. Here, the power-supply-side terminal fitting TB, the second electrical connection portion 62 of each of the two first internal conductive members 60A, and the first power supply connection portion 22A of the circuit branching member (circuit protection member) 21 are fastened and fixed together.

The frame 40 illustrated here includes, as the sub tubular portion 43, a first sub tubular portion 43A having an opening (one opening 43a) opened in the same direction as the one opening 41a of the tubular portion 41 (FIGS. 1 to 5, 8, and 13). The first sub tubular portion 43A houses the first power-supply-side electrical connection structure 70A therein, and the male screw portion of the male screw member 71 in the first power-supply-side electrical connection structure 70A protrudes from the one opening 43a of the first sub tubular portion 43A. The first sub tubular portion 43A is provided in the recess 42 of the frame 40. The tubular wall 41c of the tubular portion 41 has, as the notch 44, a first notch 44A through which the inside of the tubular portion 41 communicates with the inside of the first sub tubular portion 43A, and the second electrical connection portion 62 of the first internal conductive member 60A protrudes toward the outside the frame 40 outside the tubular portion 41 (FIG. 5). The block 30 includes, as the protruding block portion 32 to which the screw holding member 72 of the first power-supply-side electrical connection structure 70A is assembled, a first protruding block portion 32A that protrudes from the first notch 44A toward the outside of the tubular portion 41 and is housed in the first sub tubular portion 43A (FIGS. 5 and 7).

In the electrical connection box 1, the first protruding block portion 32A and the first power-supply-side electrical connection structure 70A are housed in the first sub tubular portion 43A in a state where the second electrical connection portion 62 of each of the two first internal conductive members 60A is pulled out from the one opening 43a of the first sub tubular portion 43A together with the male screw portion of the male screw member 71.

The second power supply connection portion 22B is electrically connected to the second power-supply-side electric wire WB2 and is physically and electrically connected to the second electrical connection portion 62 of the second internal conductive member 60B. The electrical connection box 1 includes a second power-supply-side electrical connection structure 70B as the power-supply-side electrical connection structure 70 that electrically connects the second power-supply-side electric wire WB2, the second electrical connection portion 62 of the second internal conductive member 60B, and the second power supply connection portion 22B of the circuit branching member (circuit protection member) 21 to each other (FIGS. 2 to 5 and 7). In the second power-supply-side electrical connection structure 70B, the male screw portion of the male screw member 71 is inserted into each of the through-holes TBa, 62a, and 22a of the power-supply-side terminal fitting TB of the terminal of the second power-supply-side electric wire WB2, the second electrical connection portion 62 of the second internal conductive member 60B, and the second power supply connection portion 22B of the circuit branching member (circuit protection member) 21, and the female screw member 73 is screwed to the male screw portion, whereby the power-supply-side terminal fitting TB, the second electrical connection portion 62 of the second internal conductive member 60B, and the second power supply connection portion 22B of the circuit branching member (circuit protection member) 21 are fastened and fixed together.

The frame 40 illustrated here includes, as the sub tubular portion 43, a second sub tubular portion 43B having an opening (one opening 43a) opened in the same direction as the one opening 41a of the tubular portion 41 (FIGS. 1 to 5, 8, and 13). The second sub tubular portion 43B houses the second power-supply-side electrical connection structure 70B therein, and the male screw portion of the male screw member 71 in the second power-supply-side electrical connection structure 70B protrudes from the one opening 43a of the second sub tubular portion 43B. The second sub tubular portion 43B is provided in the recess 42 of the frame 40. The tubular wall 41c of the tubular portion 41 has, as the notch 44, a second notch 44B through which the inside of the tubular portion 41 communicates with the inside of the second sub tubular portion 43B, and the second electrical connection portion 62 of the second internal conductive member 60B protrudes toward the outside of the frame 40 outside the tubular portion 41 (FIG. 5). The block 30 includes, as the protruding block portion 32 to which the screw holding member 72 of the second power-supply-side electrical connection structure 70B is assembled, a second protruding block portion 32B that protrudes from the second notch 44B toward the outside of the tubular portion 41 and is housed in the second sub tubular portion 43B (FIGS. 5 and 7).

In the electrical connection box 1, the second protruding block portion 32B and the second power-supply-side electrical connection structure 70B are housed in the second sub tubular portion 43B in a state where the second electrical connection portion 62 of the second internal conductive member 60B is pulled out from the one opening 43a of the second sub tubular portion 43B together with the male screw portion of the male screw member 71.

In the electrical connection box 1, the male screw portion of the male screw member 71 of the first power-supply-side electrical connection structure 70A is inserted into the through-hole 22a of the first power supply connection portion 22A to assemble the first power supply connection portion 22A to the first power-supply-side electrical connection structure 70A, and the male screw portion of the male screw member 71 of the second power-supply-side electrical connection structure 70B is inserted into the through-hole 22a of the second power supply connection portion 22B to assemble the second power supply connection portion 22B to the second power-supply-side electrical connection structure 70B. In the electrical connection box 1, the male screw portion of the male screw member 71 of the first power-supply-side electrical connection structure 70A is inserted into the through-hole TBa of the power-supply-side terminal fitting TB of the first power-supply-side electric wire WB1 to assemble the power-supply-side terminal fitting TB to the first power-supply-side electrical connection structure 70A, and the male screw portion of the male screw member 71 of the second power-supply-side electrical connection structure 70B is inserted into the through-hole TBa of the power-supply-side terminal fitting TB of the second power-supply-side electric wire WB2 to assemble the power-supply-side terminal fitting TB to the second power-supply-side electrical connection structure 70B. In the electrical connection box 1, the female screw member 73 is screwed to the male screw portion of each male screw member 71 to fasten and fix the power-supply-side terminal fitting TB of the first power-supply-side electric wire WB1, the respective second electrical connection portions 62 of the two first internal conductive members 60A, and the first power supply connection portion 22A of the circuit branching member (circuit protection member) 21 together, and fasten and fix the power-supply-side terminal fitting TB of the second power-supply-side electric wire WB2, the second electrical connection portion 62 of the second internal conductive member 60B, and the second power supply connection portion 22B of the circuit branching member (circuit protection member) 21 together. In the electrical connection box 1, the two power-supply-side terminal fittings TB and the circuit branching component (circuit protection component) 20 are assembled to the block 30 via the first power-supply-side electrical connection structure 70A and the second power-supply-side electrical connection structure 70B.

The one opening 43a of each of the first sub tubular portion 43A and the second sub tubular portion 43B is covered by the first cover member 51 together with the two power-supply-side terminal fittings TB, the second electrical connection portion 62 of each of the two first internal conductive members 60A and the second internal conductive member 60B, the first power supply connection portion 22A and the second power supply connection portion 22B of the circuit branching member (circuit protection member) 21, the first power-supply-side electrical connection structure 70A and the second power-supply-side electrical connection structure 70B, and is housed in the first cover member 51.

In the first cover member 51, the cover main body 51a, the outer peripheral wall body 51b, and the closing wall body 51c cover the one opening 43a of each of the first sub tubular portion 43A and the second sub tubular portion 43B, the first power-supply-side electric wire WB1, and the second power-supply-side electric wire WB2 together with the circuit branching component (circuit protection component) 20 from the one opening 41a side outside the tubular portion 41. Therefore, the first cover member 51 can cover the circuit branching component (circuit protection component) 20, the two power-supply-side terminal fittings TB, the respective second electrical connection portions 62 of the two first internal conductive members 60A and the second internal conductive members 60B, the first power-supply-side electrical connection structure 70A, and the second power-supply-side electrical connection structure 70B from the one opening 41a side outside the tubular portion 41. Therefore, the first cover member 51 can suppress splashing of water onto the circuit branching component (circuit protection component) 20, the power-supply-side terminal fitting TB, and the like from vertically above (from the upper side of the vehicle).

Furthermore, the first cover member 51 covers the circuit branching component (circuit protection component) 20, the two power-supply-side terminal fittings TB, the respective second electrical connection portions 62 of the two first internal conductive members 60A and the second internal conductive members 60B, the first power-supply-side electrical connection structure 70A, and the second power-supply-side electrical connection structure 70B from the facing wall body 41f side (the lateral side of the frame 40) outside the tubular portion 41 by the waterproof cover wall body 51e. Therefore, the first cover member 51 can suppress splashing of water onto the circuit branching component (circuit protection component) 20, the power-supply-side terminal fitting TB, and the like from vertically above (from the upper side of the vehicle), and can suppress splashing of water onto the circuit branching component (circuit protection component) 20, the power-supply-side terminal fitting TB, and the like from the front side of the vehicle, the rear side of the vehicle, the lateral side of the vehicle, and the like.

In addition, the first cover member 51 can prevent water splashing up from vertically below from reaching the first power-supply-side electrical connection structure 70A, the second power-supply-side electrical connection structure 70B, and the load-side electrical connection structure 75 by the waterproof cover wall body 51e. In addition, the first cover member 51 can continue to maintain the suppressing function thereof by the cover deformation suppressing portions 45 (the first cover deformation suppressing portion 45A and the second cover deformation suppressing portion 45B).

As described above, the first cover member 51 can ensure waterproofness for the circuit branching component (circuit protection component) 20, the first power-supply-side electrical connection structure 70A, the second power-supply-side electrical connection structure 70B, and the like outside the tubular portion 41.

The second cover member 52 includes, as the closing portions 53, a first closing portion 53A that closes the other opening 43b of the first sub tubular portion 43A so as not to be exposed to the outside of the frame 40, and a second closing portion 53B that closes the other opening 43b of the second sub tubular portion 43B so as not to be exposed to the outside of the frame 40 (FIGS. 1, 2, 8, and 15). The first closing portion 53A and the second closing portion 53B may be one plate-shaped wall portion that closes the other opening 43b from the outside of the frame 40 together with the first notch 44A and the second notch 44B, or may be formed of a plurality of wall portions that surrounds and covers the other opening 43b from the outside of the frame 40 together with the first notch 44A and the second notch 44B. Here, the first divided cover 52A is assembled to the second opening peripheral edge portion 41e of the tubular portion 41 on which the first sub tubular portion 43A and the second sub tubular portion 43B are provided. Therefore, the first closing portion 53A and the second closing portion 53B are provided in the first divided cover 52A.

As described above, in the electrical connection box 1 according to the present embodiment, the circuit branching component (circuit protection component) 20 is disposed outside the frame 40 and outside the tubular portion 41, and thus, it is possible to suppress an overload applied to the periphery in the housing due to the power-supply-side electric wire WB (the first power-supply-side electric wire WB1 and the second power-supply-side electric wire WB2) and the load-side electric wire WL connected to the circuit branching component (circuit protection component) 20. In particular, in the electrical connection box 1, the power-supply-side electric wire WB (the first power-supply-side electric wire WB1 and the second power-supply-side electric wire WB2) and the load-side electric wire WL are difficult to bend as the diameter of the electric wire increases, and thus, it is possible to suppress an overload applied to the periphery in the housing due to the power-supply-side electric wire WB and the like. For example, in the electrical connection box 1, the deformation of the second cover member 52 can be suppressed by suppressing an overload applied to the second cover member 52 in the housing due to the power-supply-side electric wire WB or the like. In addition, the electrical connection box 1 can improve the housing property for other electric wires in the tubular portion 41 by routing the power-supply-side electric wire WB and the like that are difficult to bend outside the frame 40. In addition, in the electrical connection box 1, the power-supply-side electric wire WB and the like are routed outside the frame 40, and thus, heat generated by the power-supply-side electric wire WB and the like does not stagnate in the housing, so that a temperature rise in the housing can be suppressed. Further, in the electrical connection box 1, it is possible to ensure waterproofness for the circuit branching component (circuit protection component) 20, the power-supply-side electrical connection structure 70 (the first power-supply-side electrical connection structure 70A and the second power-supply-side electrical connection structure 70B), and the like by the first cover member 51 while achieving these effects.

In the electrical connection box according to the present embodiment, the circuit branching component is disposed outside the tubular portion and outside the frame, and the circuit branching component is covered by the waterproof cover wall body of the cover member, so that it is possible to ensure waterproofness while suppressing an overload in the housing.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An electrical connection box comprising:
an electronic component;
an internal conductive member that electrically connects the electronic component to an external power supply;
a frame that includes a tubular portion that includes a tubular wall having an opening at least at one end and houses and holds the electronic component and the internal conductive member in the tubular portion;
a cover member that is fitted to an opening peripheral edge portion of a peripheral edge of the opening of the tubular portion and closes the opening of the tubular portion; and
a circuit branching component that is disposed outside the frame and outside the tubular portion and is interposed between the external power supply and an external load, wherein
the frame is installed such that the opening of the tubular portion faces vertically upward,
the internal conductive member includes a first electrical connection portion and a second electrical connection portion that are physically and electrically connected to the electronic component in the tubular portion,
the circuit branching component includes a power supply connection portion that is electrically connected to a power-supply-side electric wire electrically connected to the external power supply and is physically and electrically connected to the second electrical connection portion of the internal conductive member, and a load connection portion that is electrically connected to a load-side electric wire electrically connected to the external load,
the tubular wall of the tubular portion includes a facing wall body disposed to face the circuit branching component outside the tubular portion,
the cover member includes a cover main body that is disposed to face the opening of the tubular portion, an annular outer peripheral wall body that covers the opening peripheral edge portion from an outside of the tubular portion, a closing wall body that closes a gap between the cover main body and the outer peripheral wall body, an annular inner peripheral wall body that is disposed at an interval from the outer peripheral wall body on an inner side of the outer peripheral wall body and is fitted to the opening peripheral edge portion, and a waterproof cover wall body that suppresses water splashing onto the circuit branching component,
the inner peripheral wall body includes a waterproof wall portion that is fitted to a peripheral edge portion of the facing wall body that is on a side of the opening from the outside of the tubular portion and covers the peripheral edge portion of the facing wall body that is a part of the opening peripheral edge portion from the outside of the tubular portion, and
the waterproof cover wall body protrudes from the outer peripheral wall body to a position where the circuit branching component is covered between the waterproof cover wall body and the facing wall body.

2. The electrical connection box according to claim 1, wherein the frame includes at least two cover deformation suppressing portions into which a peripheral edge of the waterproof cover wall body is fitted to suppress deformation of the waterproof cover wall body in a direction away from the circuit branching component.

3. The electrical connection box according to claim 1, wherein
the second electrical connection portion is disposed outside the frame and outside the tubular portion,
the frame includes a sub tubular portion having an opening opened in the same direction as the opening of the tubular portion and bulging from the facing wall body toward an outside of the frame outside the tubular portion,
a power-supply-side electrical connection structure that electrically connects the power-supply-side electric wire, the second electrical connection portion of the internal conductive member, and the power supply connection portion of the circuit branching component to each other is provided in the sub tubular portion,
the facing wall body has a notch through which an inside of the tubular portion and an inside of the sub tubular portion communicate with each other and the second electrical connection portion of the internal conductive member protrudes toward the outside of the frame outside the tubular portion, and
the waterproof cover wall body is formed in a shape that covers the sub tubular portion and the power-supply-side electric wire together with the circuit branching component.

4. The electrical connection box according to claim 1, wherein in the circuit branching component, the power supply connection portion is disposed more adjacent to the first opening peripheral edge portion than the load connection portion in a tube axis direction of the tubular portion.

5. The electrical connection box according to claim 2, wherein in the circuit branching component, the power supply connection portion is disposed more adjacent to the first opening peripheral edge portion than the load connection portion in a tube axis direction of the tubular portion.

6. The electrical connection box according to claim 3, wherein in the circuit branching component, the power supply connection portion is disposed more adjacent to the first opening peripheral edge portion than the load connection portion in a tube axis direction of the tubular portion.
